(19) United States
(12) Patent Application Publication
(10) Pub. No.: US 2012/0076619 A1
(43) Pub. Date: Mar. 29, 2012

(54) TRANSPORT MECHANISM, TRANSPORT JIG AND TRANSPORT TRUCK

(76) Inventors: Masahiko TAKAHASHI, Kashiwazaki-shi (JP); Kenta Fukatsu, Fujisawa-shi (JP); Shuichi Kimura, Yokohama-shi (JP); Kazuhiro Teraguchi, Kashiwazaki-shi (JP)

(21) Appl. No.: 13/224,617

(22) Filed: Sep. 2, 2011

(30) Foreign Application Priority Data
Sep. 24, 2010 (JP) 2010-214479

(51) Int. Cl. H01L 21/677; B62B 3/00; B65G 65/00

(52) U.S. Cl. 414/217

(57) ABSTRACT

A transport mechanism that exchanges a workpiece between a processing chamber and a transport box arranged by mutually opposing openings while maintaining an airtight state, includes a processing chamber cap that freely opens/closes the opening of the processing chamber and also airtightly caps the opening and includes a recess in a side of the transport box, a guide mechanism that guides the processing chamber cap into the processing chamber, a workpiece support portion provided inside the processing chamber, a transport box cap that freely opens/closes the opening of the transport box and also airtightly caps the opening and is airtightly fitted into the recess, and a coupling portion that airtightly couples a front portion around the opening of the processing chamber and a front portion around the opening of the transport box.

### CROSS-REFERENCE TO RELATED APPLICATIONS

This application is based upon and claims the benefit of priority from prior Japanese Patent Application No. 2010-214479, filed Sep. 24, 2010, the entire contents of which are incorporated herein by reference.

### FIELD

The present invention relates to a transport mechanism, a transport jig, and a transport truck that transfer a workpiece such as an electrical component and an electronic component between processing chambers in a state in which, for example, a predetermined atmosphere, for example, a dry state is maintained.

### BACKGROUND

When predetermined processing is performed on a workpiece such as an electronic component constituting a secondary battery or a semiconductor component in a processing chamber, the processing chamber is maintained in a constant dry state. When the workpiece is transferred between processing chambers, on the other hand, a special carrier having an airtight structure is used for transport.

When the carrier carries a workpiece into/out of each processing chamber, the carrier carries a workpiece through an entrance using a load lock system having a double door in order to maintain the workpiece in a dry atmosphere.

The atmosphere is replaced by providing a double door in such a load lock system, which makes the mechanism more complex, and it is necessary to input a dry atmosphere again for replacement, leading to higher costs.

Thus, a transport mechanism, a transport jig, and a transport truck capable of transporting a workpiece while maintaining a predetermined atmosphere without adopting the load lock system that requires a complex mechanism and a replacement gas are desired.

### BRIEF DESCRIPTION OF THE DRAWINGS

FIG. 1 is an explanatory view schematically illustrating a processing mechanism on which a transport mechanism according to a first embodiment is mounted;

FIG. 2 is an explanatory view schematically illustrating a carrying-in process of a workpiece into the processing mechanism by the transport mechanism;

FIG. 3 is an explanatory view schematically illustrating the carrying-in process of the workpiece into the processing mechanism by the transport mechanism;

FIG. 4 is an explanatory view schematically illustrating the carrying-in process of the workpiece into the processing mechanism by the transport mechanism;

FIG. 5 is an explanatory view schematically illustrating the carrying-in process of the workpiece into the processing mechanism by the transport mechanism;

FIG. 6 is a sectional view illustrating a transport jig and a first processing chamber according to a second embodiment;

FIG. 7 is an explanatory view illustrating a carrying-out process from the first processing chamber by the transport jig;

FIG. 8 is an explanatory view illustrating the carrying-out process from the first processing chamber by the transport jig;

FIG. 9 is an explanatory view illustrating the carrying-in process into a second processing chamber by the transport jig;

FIG. 10 is an explanatory view illustrating the carrying-in process into the second processing chamber by the transport jig;

FIG. 11 is an explanatory view illustrating the carrying-in process into the second processing chamber by the transport jig;

FIG. 12 is an explanatory view illustrating the carrying-in process into the second processing chamber by the transport jig;

FIG. 13 is an explanatory view illustrating the carrying-in process into the second processing chamber by the transport jig;

FIG. 14 is an explanatory view illustrating the carrying-in process into the second processing chamber by the transport jig;

FIG. 15 is a longitudinal sectional view illustrating a transport truck according to a third embodiment;

FIG. 16 is an explanatory view illustrating an accommodation process of the workpiece by the transport truck; and

FIG. 17 is an explanatory view illustrating the accommodation process of the workpiece by the transport truck.

### DETAILED DESCRIPTION

A transport mechanism according to an embodiment is a transport mechanism that exchanges a workpiece between a processing chamber and a transport box arranged by mutually opposing openings while maintaining an airtight state, including: a processing chamber cap that freely opens/closes the opening of the processing chamber and also airtightly caps the opening and includes a recess in a side of the transport box; a guide mechanism that guides the processing chamber cap into the processing chamber; a workpiece support portion provided inside the processing chamber; a transport box cap that freely opens/closes the opening of the transport box and also airtightly caps the opening and is airtightly fitted into the recess; and a coupling portion that airtightly couples a front portion around the opening of the processing chamber and a front portion around the opening of the transport box.

A transport jig according to an embodiment includes: an accommodation chamber in a bottomed cylindrical shape; an inner cylinder provided coaxially with the accommodation chamber; an outer cylinder provided removably on an outer circumferential surface of the inner cylinder to hold a workpiece; a cap provided on an outer circumferential surface of the outer cylinder to cap the opening of the accommodation chamber openably and airtightly; a projection portion provided freely axially reciprocatable inside the inner cylinder; and an engaging portion provided in the projection portion to engage with the outer cylinder.

A transport truck according to an embodiment includes: an accommodation chamber to accommodate a workpiece; an opening provided on a side face of the accommodation chamber; a shaft member whose base end is provided in the accommodation chamber and whose tip projects to the outside from the opening, and which extends perpendicularly to the opening; a chuck mechanism opened/closed by being driven from outside the accommodation chamber; a workpiece support member arranged freely reciprocatingly with respect to the shaft member to support the workpiece; an engaging portion provided in the workpiece support member and inserted/removed by the chuck mechanism being opened/closed; and a cap provided in the workpiece support member to openably close the opening from outside the accommodation chamber.

### First Embodiment

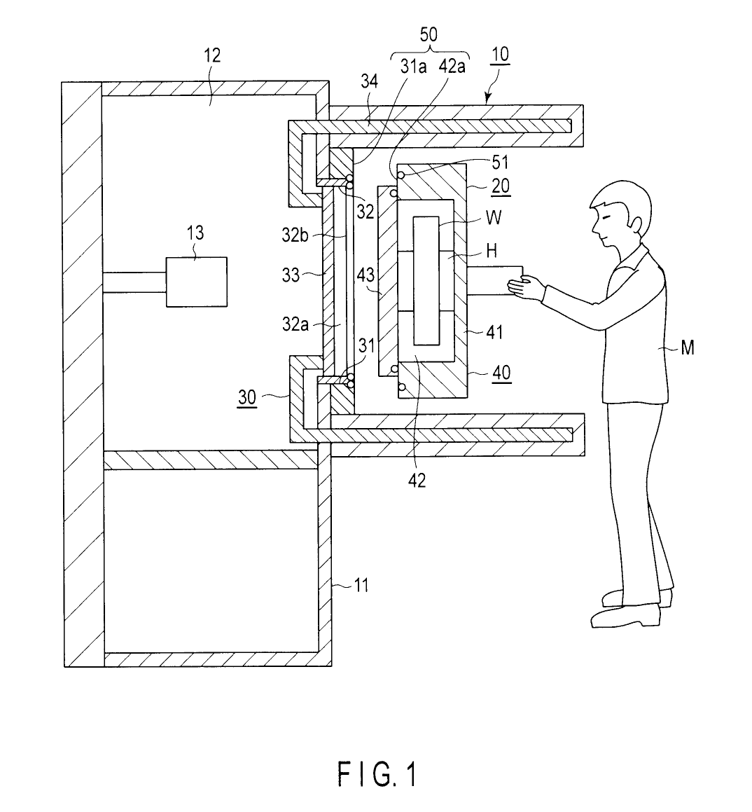

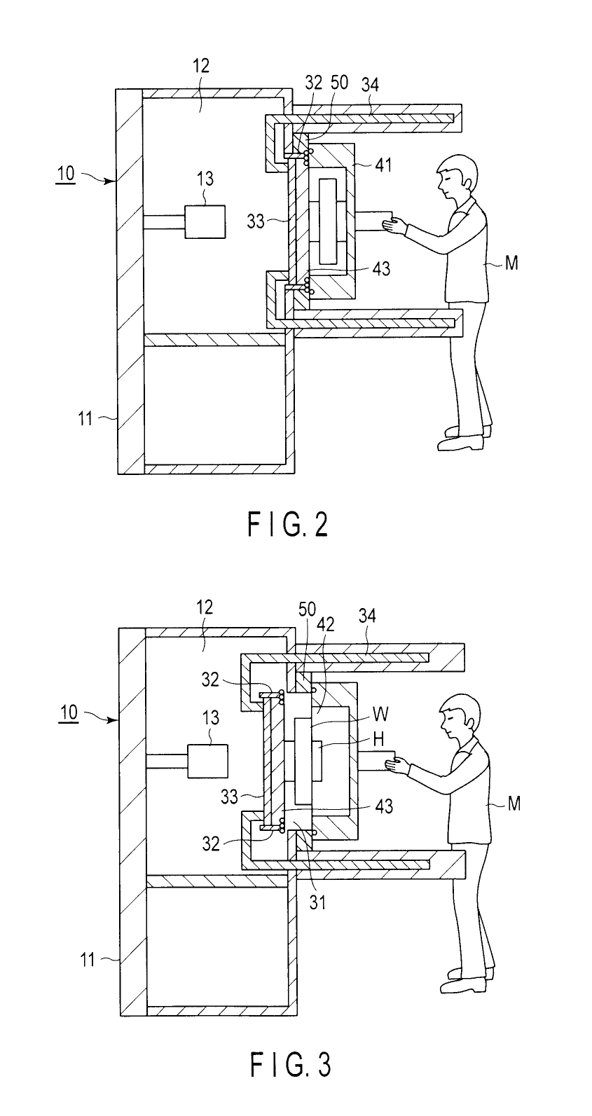

FIG. 1 is an explanatory view schematically illustrating a processing mechanism 10 on which a transport mechanism 20 according to the first embodiment is mounted and FIGS. 2 to 5 are explanatory views schematically illustrating a carrying-in process of a workpiece W into the processing mechanism 10 by the transport mechanism 20. The inside of each of a processing chamber 12 and a transport box 41 described later is maintained in a dry atmosphere (for example, the dew point: −60° C.) and a common atmosphere (for example, the dew point: −20° C.) is outside the processing chamber 12 and the transport box 41. In these figures, reference number M indicates an operator.

The processing mechanism 10 includes a rack 11 placed on a floor and the processing chamber 12 provided on the rack 11 airtightly. A fulcrum 13 to support a framework 32 described later is provided in the processing chamber 12. The transport mechanism 20 includes a receiving mechanism 30 provided on the processing chamber 12 side and a workpiece transport unit 40 arranged opposite to the processing chamber 12.

The receiving mechanism 30 includes an opening 31 provided on the front side of the processing chamber 12, the framework 32 airtightly fitted along an inner frame of the opening 31, a processing chamber cap 33 formed integrally with the framework 32 and closed, and a guide mechanism 34 that supports the processing chamber cap 33 from the processing chamber 12 side for guidance from the opening 31 horizontally toward the inner side of the processing chamber 12. A recess 32a is formed on the right side of the framework 32 in FIG. 1 so that a transport box cap 43 described later is airtightly fitted thereinto by an O-ring 32b.

The workpiece transport unit 40 includes the transport box 41 in a rectangular parallelepiped shape, an opening 42 provided on the front side of the transport box 41, and the transport box cap 43 that freely opens/closes the opening 42 and also airtightly caps the opening 42. The workpiece W and a workpiece holding portion H that holds the workpiece W and is mounted on the transport box cap 43 are accommodated inside the transport box 41. The opening 31 of the processing chamber 12 and the opening 42 of the transport box 41 are arranged opposite to each other.

A front portion 31a around the opening 31 of the processing chamber 12 and a front portion 42a around the opening 42 of the transport box 41 come into contact to become a coupling portion 50 that couples airtightly. The coupling portion 50 includes an O-ring 51.

The material of the processing chamber cap 33 and the transport box cap 43 is, for example, Teflon (registered trademark), Zeonor, SUS pure products, SUS bright products, pure aluminum materials or fluorine coated. If these materials are used or coated with fluorine, the amount of moisture adsorption is reduced so that a dry atmosphere inside can be maintained.

The transport mechanism 20 configured as described above carries in the workpiece W inside the transport box 41 into the processing chamber 12 while maintaining a dry atmosphere as described below. While being assisted by a transport truck (not illustrated), the operator M brings the transport box 41 of the workpiece transport unit 40 closer to the receiving mechanism 30. Then, as illustrated in FIG. 2, the operator M fits the transport box cap 43 into the recess 32a. At the same time, the front portion 31a of the processing chamber 12 and the front portion 42a of the transport box 41 come into contact to airtightly couple by forming the coupling portion 50. At this point, the processing chamber cap 33 and the transport box cap 43 are mutually in close contact.

Next, when, as illustrated in FIG. 3, the processing chamber cap 33 is moved by the guide mechanism 34, the transport box cap 43 is integrally moved via the framework 32 to the left in FIG. 3. The workpiece holding portion H is mounted on the transport box cap 43 and thus, the workpiece W is also carried into the processing chamber 12. Because the front portion 31a of the processing chamber 12 and the front portion 42a of the transport box 41 are airtightly in contact, no outside air flows in.

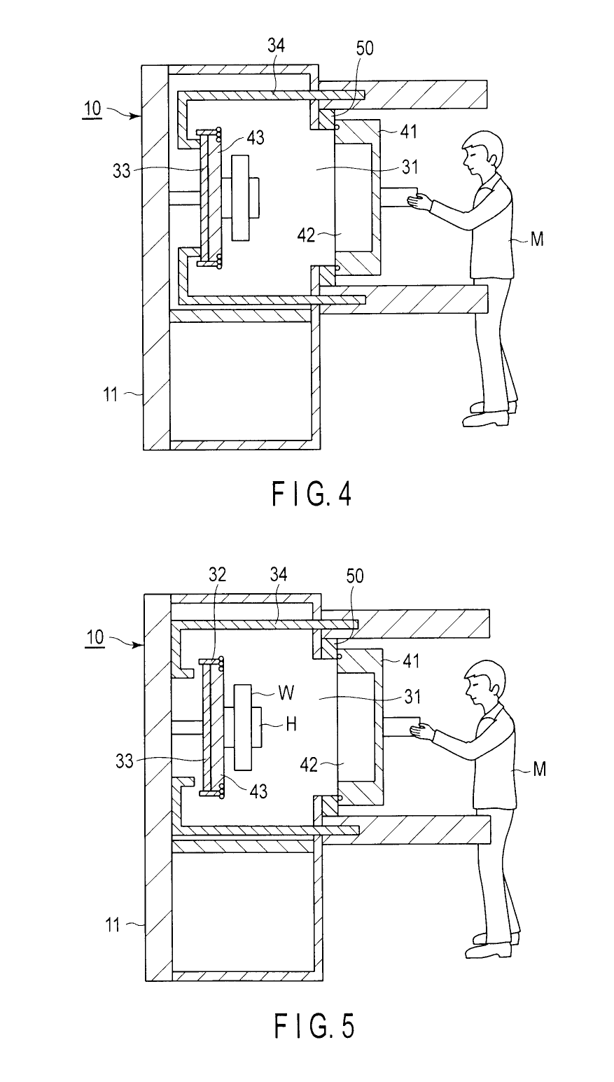

Further, when, as illustrated in FIG. 4, the processing chamber cap 33 is moved by the guide mechanism 34 as far as inside the processing chamber 12, the framework 32 is chucked by the fulcrum 13 and the movement stops. Further, as illustrated in FIG. 5, the guide mechanism 34 moves to the left in FIG. 5 to separate from the processing chamber cap 33. In this state, processing on the workpiece W is started.

Thus, the transport mechanism 20 according to the present embodiment can carry in the workpiece W while maintaining a dry atmosphere by bringing the processing chamber cap 33 and the transport box cap 43 into close contact to eliminate room for a portion exposed to outside air. When the workpiece W is carried out, the procedure is reversed.

Therefore, there is no need to use a load lock system in which a double door is provided and a workpiece can be transported at low cost while maintaining a predetermined atmosphere with a simple configuration and without using a replacement gas.

### Second Embodiment

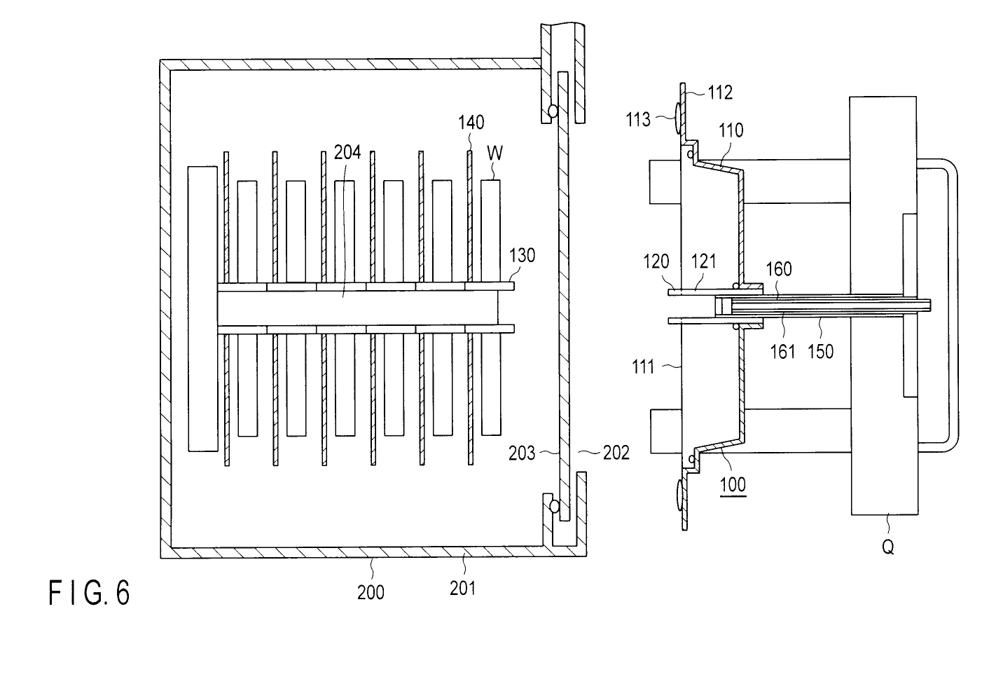

FIG. 6 is a sectional view illustrating a transport jig 100 according to the second embodiment.

The transport jig 100 has a function to transport a workpiece W from a first processing chamber 200 to a second processing chamber 210 while maintaining a dry atmosphere. Reference symbol Q in FIG. 6 indicates a transport truck.

The transport jig 100 includes an accommodation chamber 110 in a bottomed cylindrical shape supported by the transport truck Q, an inner cylinder 120 provided coaxially with the accommodation chamber 110 and airtightly, a projection portion 150 provided freely axially reciprocatable inside the inner cylinder 120, and a engaging portion 160 provided inside the projection portion 150 to removably engage an outer cylinder 130.

In FIG. 6, reference number 130 is an outer cylinder removably provided on an outer circumferential surface of the inner cylinder 120 and reference number 140 is a cap provided on the outer circumferential surface of the outer cylinder 130 to freely open/close an opening 111 of the accommodation chamber 110 and also to cap the opening 111 airtightly. The outer cylinder 130 has a function to hold the workpiece W on the outer circumferential surface thereof.

The accommodation chamber 110 is provided with a collar 112 and packing 113 is arranged around the opening 111.

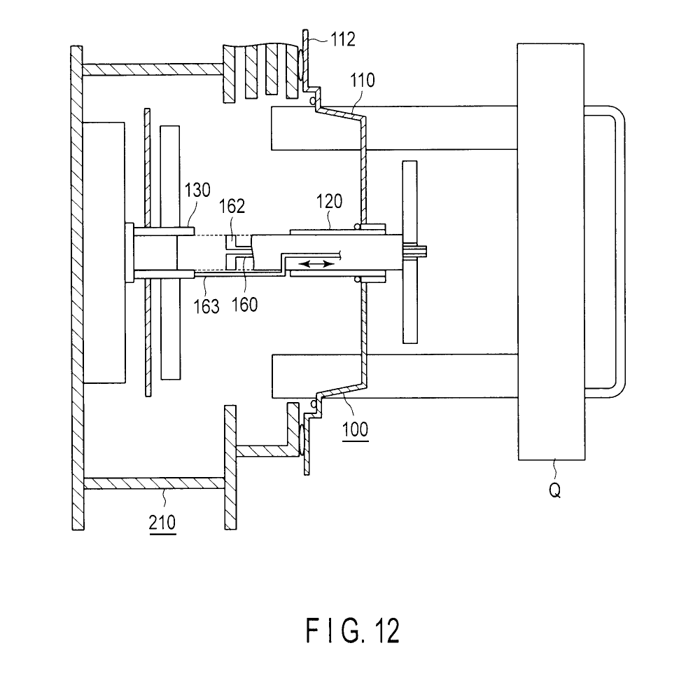

The inner cylinder 120 includes an axially formed groove 121 to allow a pin 162, described later, to pass. The outer cylinder 130 includes a hole (not illustrated), formed in an inner circumferential surface thereof, with which the pin 162 engages. The engaging portion 160 includes a pair of operation rods 161 extending axially, the pin 162 projecting from the operation rods 161 diametrically outwardly, and a pushdown rod 163 (see FIG. 12) extending axially and capable of moving axially, and whose tip is opposite to an end of the outer cylinder 130.

The first processing chamber 200 includes a cabinet 201 formed airtightly, a sliding door 203 provided in an opening 202 of the cabinet 201, and a workpiece holding portion 204 in an axial shape to hold the workpiece W.

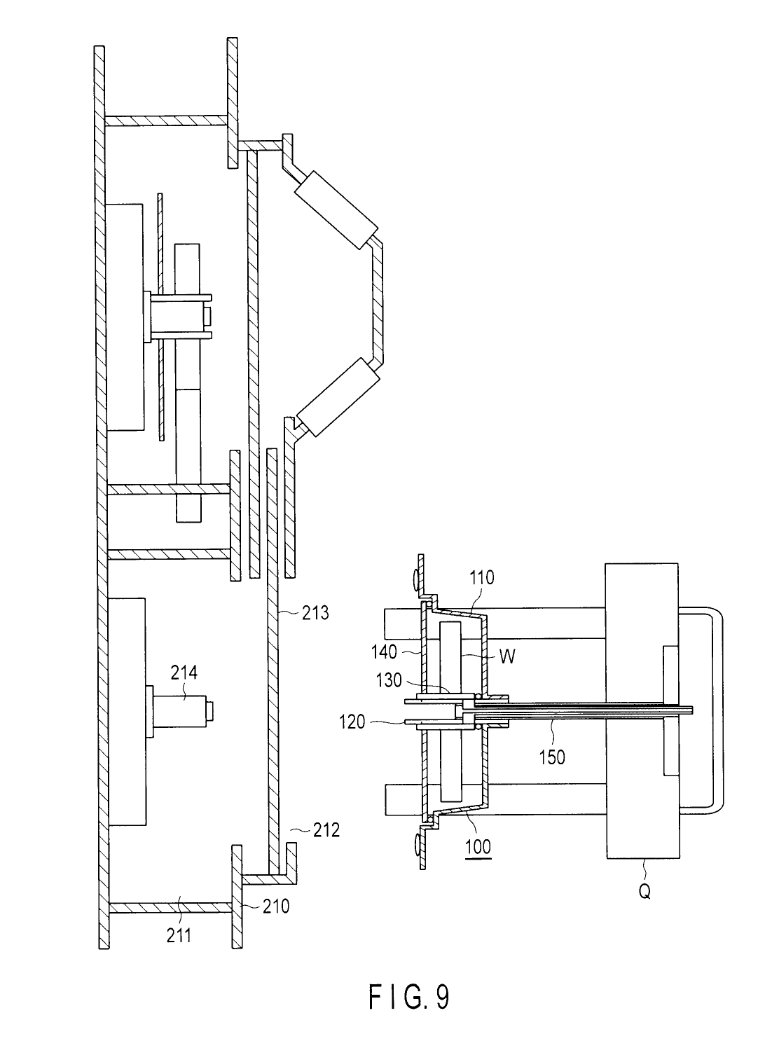

The second processing chamber 210 includes, as illustrated in FIG. 9, a cabinet 211 formed airtightly, a sliding door 213 provided in an opening 212 of the cabinet 211, and a workpiece holding portion 214 in an axial shape to hold the workpiece W.

The transport jig 100 configured as described above transports the workpiece W from the first processing chamber 200 to the second processing chamber 210 as described below. A plurality of outer cylinders 130 is held in the workpiece holding portion 204 of the cabinet 201 of the first processing chamber 200 by being arrayed axially. The workpiece W is held by the outer cylinder 130.

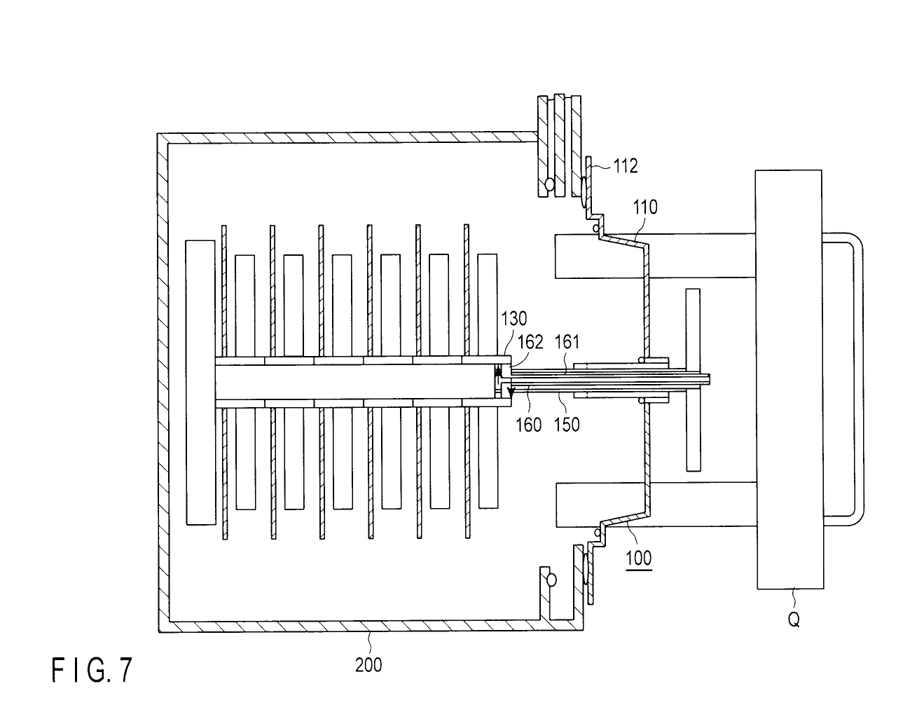

As illustrated in FIG. 6, the accommodation chamber 110 is opposed to the opening 202 of the first processing chamber 200. Next, as illustrated in FIG. 7, the opening 111 of the accommodation chamber 110 is opposed to the opening 202 of the first processing chamber 200. In this case, the collar 112 of the accommodation chamber 110 is brought into close contact with the cabinet 201 of the first processing chamber 200 via the packing 113 and thus, an airtight state is maintained while the accommodation chamber 110 and the first processing chamber 200 are communicatively connected. In this state, the sliding door 203 is opened and the projection portion 150 is abutted against the workpiece holding portion 204. Here, the pin 162 is opened to the outside to engage with the hole of the outer cylinder 130.

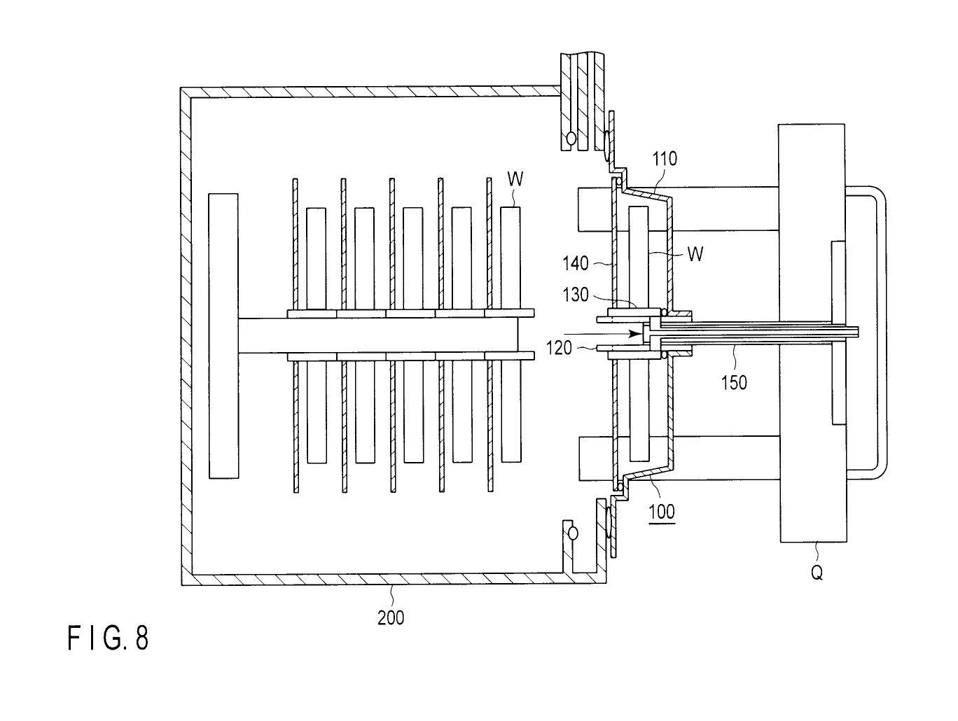

Next, as illustrated in FIG. 8, the projection portion 150 is moved to the right in FIG. 8 to fit the outer cylinder 130 into the inner cylinder 120. At this point, the pin 162 projects to the outer diameter side, but the groove 121 is formed in the inner cylinder 120 and thus, the outer cylinder 130 is moved, as illustrated, up to the depth side. Accordingly, the cap 140 provided in the outer cylinder 130 closes the opening 111 and the accommodation chamber 110 is maintained in an airtight state and is not exposed to outside air so that the dry atmosphere is maintained. Then, the sliding door 203 is closed.

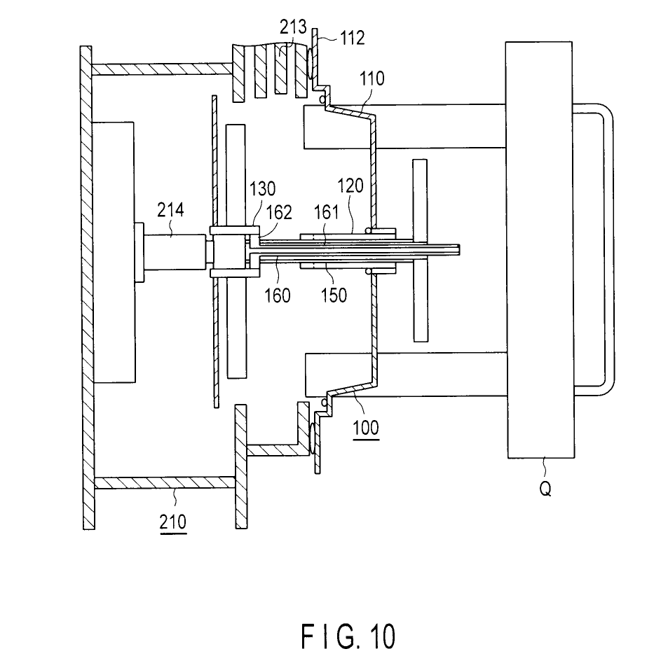

Next, the transport jig 100 is moved to the second processing chamber 210 by the transport truck Q. As illustrated in FIG. 9, the accommodation chamber 110 is opposed to the opening 212 of the second processing chamber 210. Next, as illustrated in FIG. 10, the opening 111 of the accommodation chamber 110 is opposed to the opening 212 of the second processing chamber 210. In this case, the collar 112 of the accommodation chamber 110 is brought into close contact with the cabinet 211 of the second processing chamber 210 via the packing 113 and thus, an airtight state is maintained while the accommodation chamber 110 and the second processing chamber 210 are communicatively connected. In this state, the sliding door 213 is opened and the projection portion 150 is abutted against the workpiece holding portion 214.

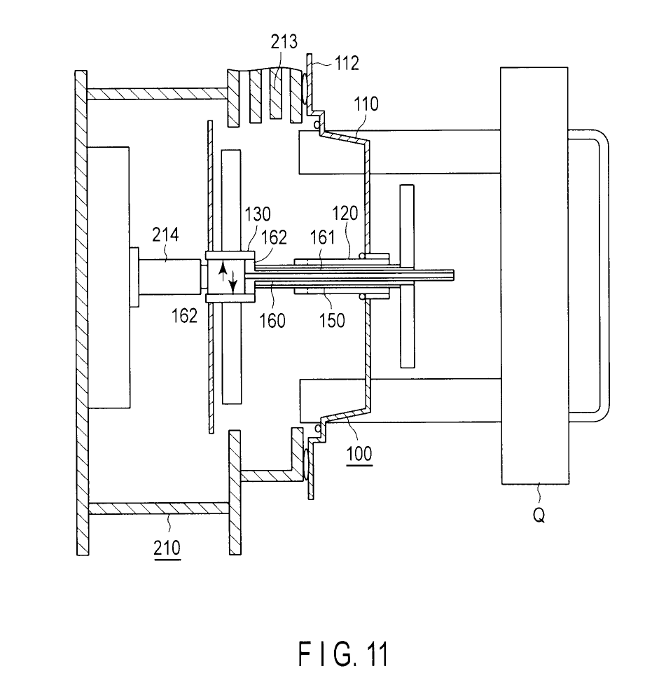

As illustrated in FIG. 11, the pin 162 is closed to the inside to disengage from the hole of the outer cylinder 130. Further, as illustrated in FIG. 12, an end of the outer cylinder 130 is pushed by the pushdown rod 163 to transfer the outer cylinder 130 to the workpiece holding portion 214.

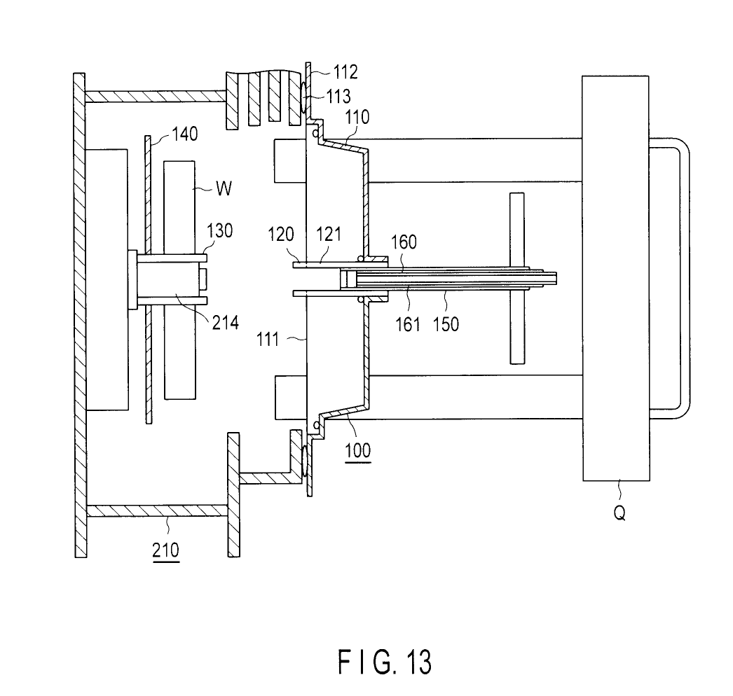

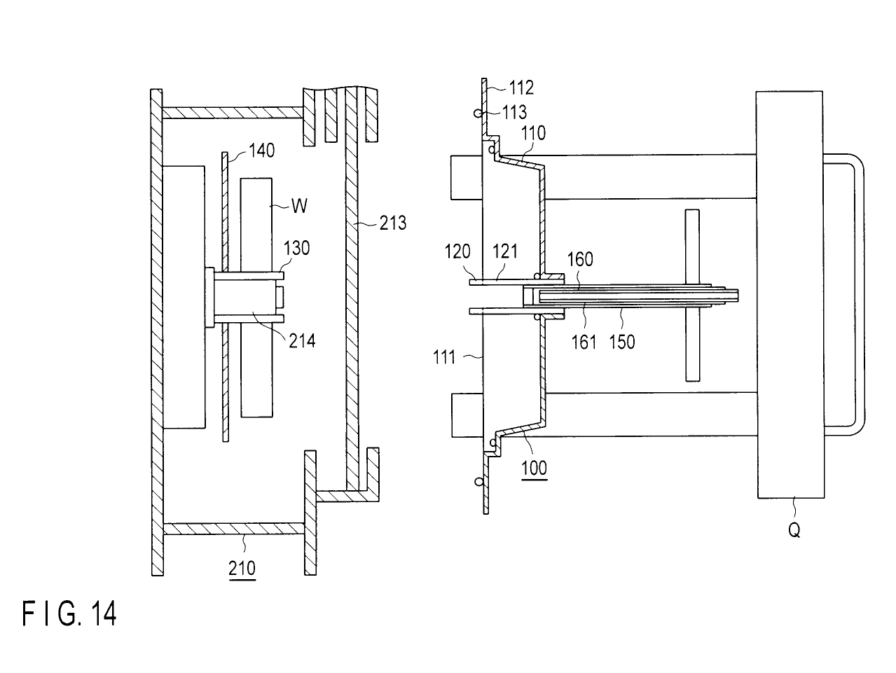

Next, as illustrated in FIG. 13, the projection portion 150 is moved to the right in FIG. 13. Then, as illustrated in FIG. 14, the transport truck Q is separated from the second processing chamber 210 and the sliding door 203 is closed.

Thus, in the transport jig 100 according to the present embodiment, the opening 110 of the transport jig 100 and the opening of a processing chamber are opposed to directly carry the cap 140 into the processing chamber and therefore, the workpiece W can be carried in while a dry atmosphere is maintained.

Therefore, there is no need to use a load lock system in which a double door is provided and a workpiece can be transported at low cost while maintaining a predetermined atmosphere with a simple configuration and without using a replacement gas.

### Third Embodiment

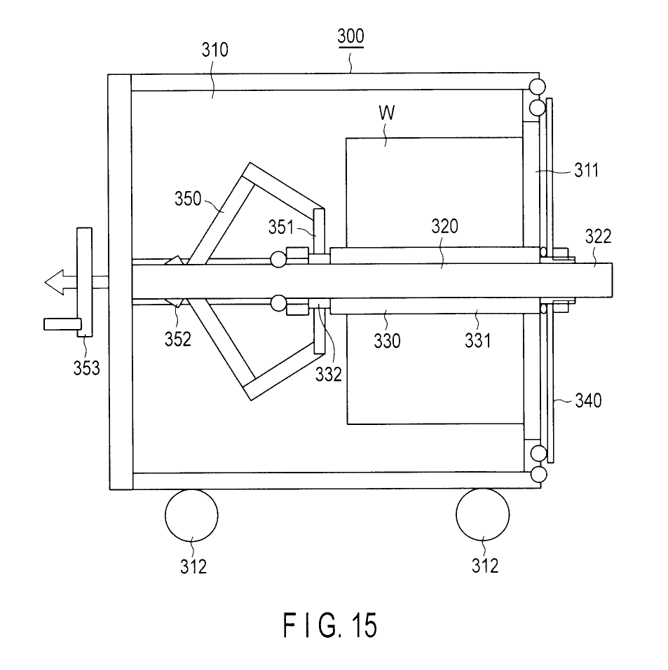

FIG. 15 is a longitudinal sectional view illustrating a transport truck 300 according to the third embodiment. The transport truck 300 has a function to transport a workpiece W in a state in which a dry atmosphere is maintained.

The transport truck 300 includes an accommodation chamber 310 to accommodate the workpiece W. The accommodation chamber 310 is provided with an opening 311 on the side and also provided with a truck 312 at the bottom.

The accommodation chamber 310 is provided with a shaft member 320. A base end 321 of the shaft member 320 is mounted on an inner wall surface of the accommodation chamber 310 and a tip 322 thereof projects from the opening 311 to the outside. The axis of the shaft member 320 and the opening 311 intersect at right angles.

A workpiece support member 330 in a cylindrical shape is provided on the outer circumferential surface of the shaft member 320 freely axially reciprocatable relative to the shaft member 320. A holding portion 331 that removably holds the workpiece W is formed around the workpiece support member 330. Also, an engaging portion 332 engaged with a chuck mechanism 350 described later is formed on the left end side of the workpiece support member 330 in FIG. 15. Also, a cap 340 that closes the opening 311 from outside is mounted on the right end side of the workpiece support member 330 in FIG. 15.

The chuck mechanism 350 is provided coaxially with the shaft member 320 on the base end 321 side of the shaft member 320. The chuck mechanism 350 includes a claw portion 351 that engages with/disengages from the engaging portion 332 through the opening/closing thereof, a link mechanism 352 that pulls the claw portion 351 to the tip side while being closed, and a rotating handle 353 that drives the link mechanism 352 from outside the accommodation chamber 310.

The transport truck 300 configured as described above transports the workpiece W as described below.

The transport truck 300 is carried into the processing chamber (not illustrated) where the workpiece W is placed. At this point, the workpiece support member 330 is not mounted.

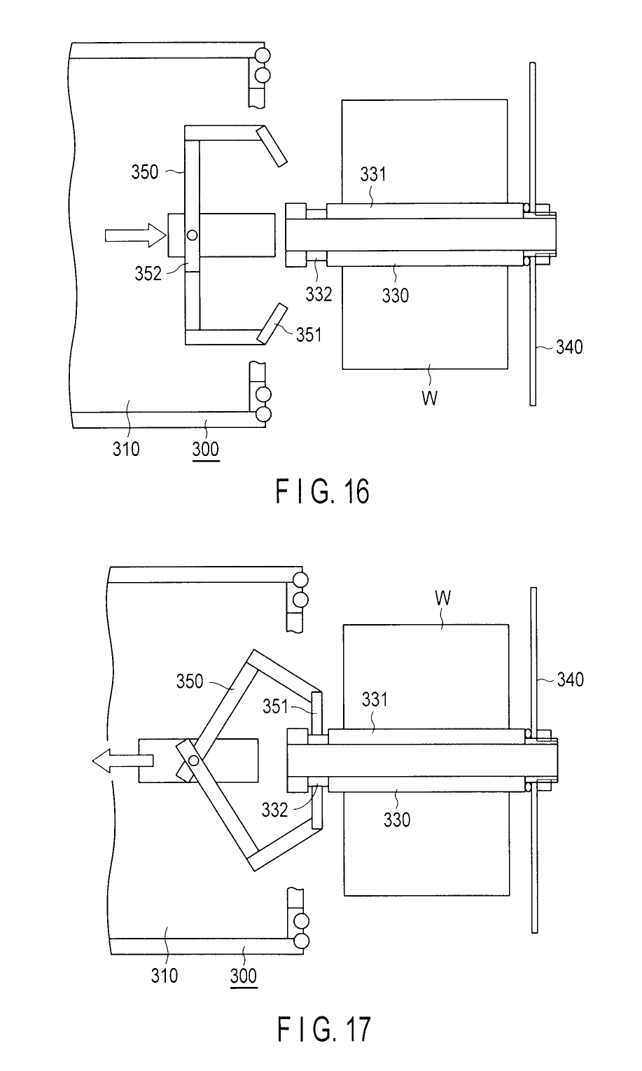

Next, as illustrated in FIG. 16, the rotating handle 353 is rotated to move the claw portion 351 up to the opening 311 in an opened state. In the processing chamber, the workpiece support member 330 on which the workpiece W is mounted is brought closer to the opening 311 to pass the shaft member 320 through a hollow portion inside the workpiece support member 330.

Next, the rotating handle 353 is rotated to close, as illustrated in FIG. 17, the claw portion 351 to engage the claw portion 351 with the engaging portion 332. Further, the rotating handle 353 is rotated to bring the claw portion 351 into the accommodation chamber 310.

Finally, as illustrated in FIG. 15, the workpiece support member 330 is brought in until the cap 340 closes the opening 311. Then, the transport truck 300 is moved to another processing chamber (not illustrated). By opening/closing the cap 340 inside the processing chamber, the dry atmosphere in the processing chamber can be maintained also inside the accommodation chamber 310 of the transport truck 300.

Thus, the transport truck 300 according to the present embodiment can carry in the workpiece W while maintaining a dry atmosphere by directly entering a processing chamber and opening/closing the cap 340 inside the processing chamber.

Therefore, there is no need to use a load lock system in which a double door is provided and the workpiece W can be transported at low cost while maintaining a predetermined atmosphere with a simple configuration and without using a replacement gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A transport mechanism that exchanges a workpiece between a processing chamber and a transport box arranged by mutually opposing openings while maintaining an airtight state, comprising:
a processing chamber cap that freely opens/closes the opening of the processing chamber and also airtightly caps the opening and includes a recess in a side of the transport box;
a guide mechanism that guides the processing chamber cap into the processing chamber;
a workpiece support portion provided inside the processing chamber;
a transport box cap that freely opens/closes the opening of the transport box and also airtightly caps the opening and is airtightly fitted into the recess; and
a coupling portion that airtightly couples a front portion around the opening of the processing chamber and a front portion around the opening of the transport box.

2. The transport mechanism according to claim 1, wherein
the processing chamber cap or the transport box cap is formed of a material with less amount of moisture adsorption.

3. A transport jig, comprising:
an accommodation chamber in a bottomed cylindrical shape;
an inner cylinder provided coaxially with the accommodation chamber;
an outer cylinder provided removably on an outer circumferential surface of the inner cylinder to hold a workpiece;
a cap provided on an outer circumferential surface of the outer cylinder to cap the opening of the accommodation chamber openably and airtightly;
a projection portion provided freely axially reciprocatable inside the inner cylinder; and
an engaging portion provided in the projection portion to engage with the outer cylinder.

4. The transport jig according to claim 3, wherein
the cap is formed of a material with less amount of moisture adsorption.

5. A transport truck, comprising:
an accommodation chamber to accommodate a workpiece;
an opening provided on a side face of the accommodation chamber;
a shaft member whose base end is provided in the accommodation chamber and whose tip projects to an outside from the opening, and which extends perpendicularly to the opening;
a chuck mechanism opened/closed by being driven from outside the accommodation chamber;
a workpiece support member arranged freely reciprocatingly with respect to the shaft member to support the workpiece;
an engaging portion provided in the workpiece support member and inserted/removed by the chuck mechanism being opened/closed; and
a cap provided in the workpiece support member to openably close the opening from outside the accommodation chamber.

6. The transport truck according to claim 5, wherein
the workpiece support member is slidably formed on an outer circumferential surface of the shaft member.

7. The transport truck according to claim 5, wherein
the chuck mechanism is formed coaxially with the shaft member.

8. The transport truck according to claim 5, wherein
the cap is formed of a material with less amount of moisture adsorption.
